(19) United States
(12) Patent Application Publication
(10) Pub. No.: US 2008/0087950 A1
(43) Pub. Date: Apr. 17, 2008

(54) Semiconductor device manufacturing method

(75) Inventor: Yasuhiko Ueda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory Inc., Tokyo (JP)

(21) Appl. No.: 11/907,715

(22) Filed: Oct. 16, 2007

(30) Foreign Application Priority Data
Oct. 17, 2006 (JP) 2006-282981

(51) Int. Cl. H01L 29/78; H01L 21/336

(52) U.S. Cl. 257/330; 438/8; 257/E21.41; 257/E29.262

(57) ABSTRACT

Before forming a gate trench, a buried oxide film forming an element isolation region is selectively etched, thereby exposing a side-wall shoulder portion, having a rounded shape, of an active region. This reduces a range in which an end portion of the buried oxide film serves as a mask when forming the gate trench. After this, the gate trench is formed. This makes it possible to reduce silicon that remains on a side wall of the element isolation region adjacent to the gate trench.

This application is based upon and claims the benefit of priority from Japanese application No. 2006-282981, filed on Oct. 17, 2006, the disclosure of which is incorporated herein in its entirety by reference.

### BACKGROUND OF THE INVENTION

This invention relates to a method of manufacturing a semiconductor device and, in particular, relates to a method of manufacturing a DRAM (Dynamic Random Access Memory) having trench-gate transistors.

In recent years, MOS transistor gates have been miniaturized following the high integration of semiconductor devices and a phenomenon called a short channel effect has arisen as a problem. As one of methods for preventing occurrence of this short channel effect, there is a trench gate technique that forms a trench under a gate and uses the bottom of the trench as a channel, thereby achieving a necessary and sufficient channel length. A semiconductor device having trench gates is described, for example, in Japanese Unexamined Patent Application Publication (JP-A) No. 2005-311317.

### SUMMARY OF THE INVENTION

In a semiconductor device such as a DRAM, trench-gate transistors are used for cells for the purpose of high integration. On the other hand, planar transistors are used for a peripheral circuit because the high-speed operation is required. In the semiconductor device in which the transistors of different types are formed on the same substrate as described above, an element isolation region is formed so as to have inclined side walls in order to relax stresses generated in the substrate and facilitate formation of a buried oxide film. Further, for improving the transistor characteristics, a side-wall shoulder portion of each of active regions adjacent to the element isolation region should be formed into a rounded shape. As a result, after the formation of the element isolation region, end portions of the buried oxide film cover the side-wall shoulder portions (rounded portions) of the active regions. The end portions of the buried oxide film covering the active regions serve as masks in etching for forming gate trenches. Further, since the side walls of the element isolation region are inclined, the influence thereof increases as the depth increases in a depth direction of the gate trenches. As a result, silicon etching residues remain on the side walls of the element isolation region.

The silicon etching residues remaining on the side walls of the element isolation region serve as parasitic channels to impair the normal operation of the transistors and thus should be removed. In a related trench gate forming method, sacrificial oxidation and oxide film wet etching are performed for removing the silicon etching residues. However, since the silicon etching residues are each thick, it is necessary that the sacrificial oxidation amount and the wet etching amount be large. Therefore, there is a problem that the width of the trenches formed in the active regions increases to thus make it impossible to form the transistors precisely following the design size. Further, there is also a problem that large recesses are formed in the element isolation region due to the wet etching and thus the flatness of the surface is irregularly impaired, resulting in a reduction in manufacturing yield.

It is therefore an object of this invention to provide a method of manufacturing a semiconductor device having a trench-gate transistor precisely following the design size, by removing, prior to forming a trench, a cause itself of occurrence of a silicon etching residue on a side wall of an element isolation region.

According to an aspect of this invention, a method of manufacturing a semiconductor device has a trench-gate transistor in an active region surrounded by an element isolation region. The method includes the steps of forming a buried oxide film in the element isolation region and flattening the buried oxide film; selectively etching the buried oxide film in a region adjacent to a trench-forming region, so that a position of an upper surface of the buried oxide film in the region adjacent to the trench-forming region is located lower than a position of an upper surface of the active region; and forming, thereafter, a gate trench in the trench-forming region.

According to another aspect of this invention, a semiconductor device has a trench-gate transistor in an active region surrounded by an element isolation region. The semiconductor device manufactured by the steps of forming a buried oxide film in the element isolation region and flattening the buried oxide film; selectively etching the buried oxide film in a region adjacent to a trench-forming region, so that a position of an upper surface of the buried oxide film in the region adjacent to the trench-forming region is located lower than a position of an upper surface of the active region; and forming, thereafter, a gate trench in the trench-forming region.

### BRIEF DESCRIPTION OF THE DRAWINGS

FIG. 1 is a plan view showing memory cells of a DRAM having a plurality of active regions;

FIGS. 2A, 2B, and 2C are a plan view of one of the active regions, a sectional view in its long-side direction, and a sectional view in its short-side direction, respectively, for explaining one process of a related trench gate forming method;

FIGS. 3A, 3B, and 3C are a plan view of the active region, a sectional view in its long-side direction, and a sectional view in its short-side direction, respectively, for explaining a process subsequent to the process of FIGS. 2A-2C;

FIGS. 4A, 4B, and 4C are a plan view of the active region, a sectional view in its long-side direction, and a sectional view in its short-side direction, respectively, for explaining a process subsequent to the process of FIGS. 3A-3C;

FIGS. 5A, 5B, and 5C are a plan view of the active region, a sectional view in its long-side direction, and a sectional view in its short-side direction, respectively, for explaining a process subsequent to the process of FIGS. 4A-4C;

FIGS. 6A, 6B, and 6C are a plan view of the active region, a sectional view in its long-side direction, and a sectional view in its short-side direction, respectively, for explaining a process subsequent to the process of FIGS. 5A-5C;

FIGS. 7A, 7B, and 7C are a plan view of the active region, a sectional view in its long-side direction, and a sectional view in its short-side direction, respectively, for explaining a process subsequent to the process of FIGS. 6A-6C;

FIGS. 8A, 8B, and 8C are a plan view of the active region, a sectional view in its long-side direction, and a sectional view in its short-side direction, respectively, for explaining a process subsequent to the process of FIGS. 7A-7C;

FIGS. 9A, 9B, and 9C are a plan view of the active region, a sectional view in its long-side direction, and a sectional view in its short-side direction, respectively, for explaining a process subsequent to the process of FIGS. 8A-8C;

FIGS. 10A, 10B, and 10C are a plan view of the active region, a sectional view in its long-side direction, and a sectional view in its short-side direction, respectively, for explaining a process subsequent to the process of FIGS. 9A-9C;

FIGS. 11A, 11B, and 11C are a plan view of the active region, a sectional view in its long-side direction, and a sectional view in its short-side direction, respectively, for explaining a process subsequent to the process of FIGS. 10A-10C;

FIGS. 12A, 12B, and 12C are a plan view of the active region, a sectional view in its long-side direction, and a sectional view in its short-side direction, respectively, for explaining a process, subsequent to the process of FIGS. 4A-4C, of a semiconductor device manufacturing method according to a first embodiment of this invention;

FIG. 13 is a graph showing changes in the ratio between SiF luminescence intensity and CF luminescence intensity with respect to the etching time;

FIGS. 14A, 14B, and 14C are a plan view of the active region, a sectional view in its long-side direction, and a sectional view in its short-side direction, respectively, for explaining a process subsequent to the process of FIGS. 12A-12C;

FIGS. 15A, 15B, and 15C are a plan view of the active region, a sectional view in its long-side direction, and a sectional view in its short-side direction, respectively, for explaining a process subsequent to the process of FIGS. 14A-14C;

FIGS. 16A, 16B, and 16C are a plan view of the active region, a sectional view in its long-side direction, and a sectional view in its short-side direction, respectively, for explaining a process subsequent to the process of FIGS. 15A-15C;

FIG. 17 is a sectional view in a long-side direction of the active region for explaining a process subsequent to the process of FIGS. 16A-16C;

FIGS. 18A, 18B, and 18C are a plan view of the active region, a sectional view in its long-side direction, and a sectional view in its short-side direction, respectively, for explaining a process, subsequent to the process of FIGS. 2A-2C or FIGS. 3A-3C, of a semiconductor device manufacturing method according to a second embodiment of this invention; and

FIGS. 19A, 19B, and 19C are a plan view of the active region, a sectional view in its long-side direction, and a sectional view in its short-side direction, respectively, for explaining a process subsequent to the process of FIGS. 18A-18C.

### DESCRIPTION OF THE PREFERRED EMBODIMENTS

Hereinbelow, embodiments of this invention will be described with reference to the drawings.

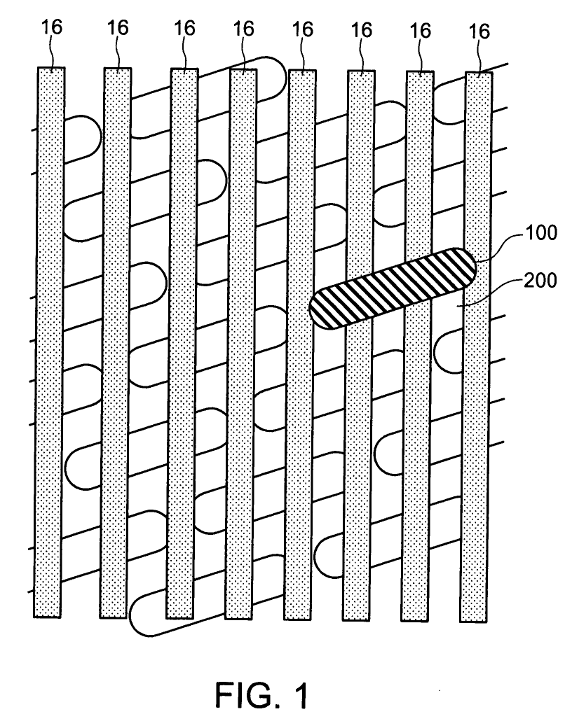

At first, in order to facilitate understanding of this invention, the related trench gate forming method will be described with reference to FIGS. 1 to 11C.

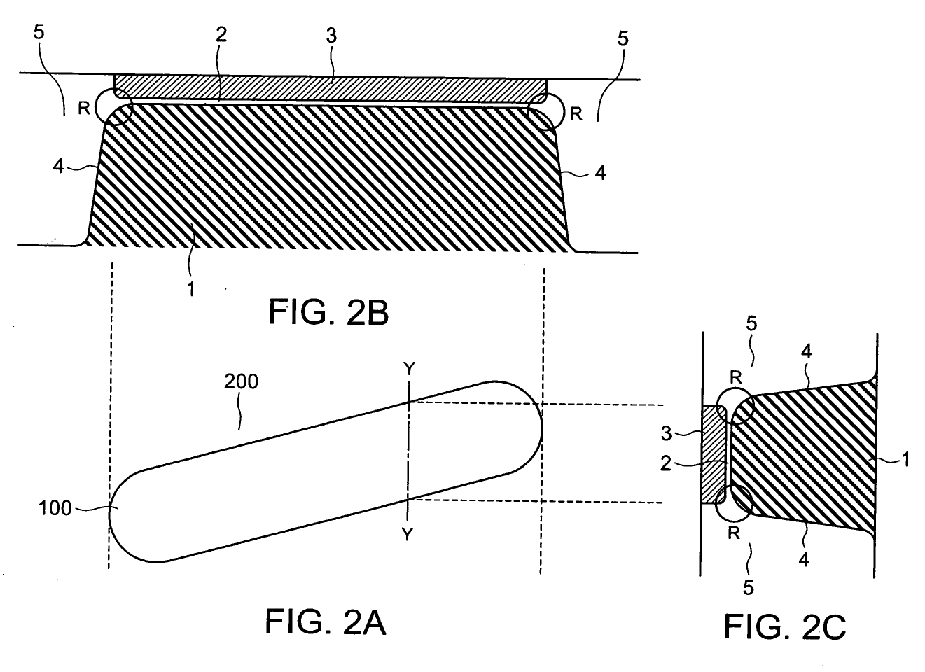

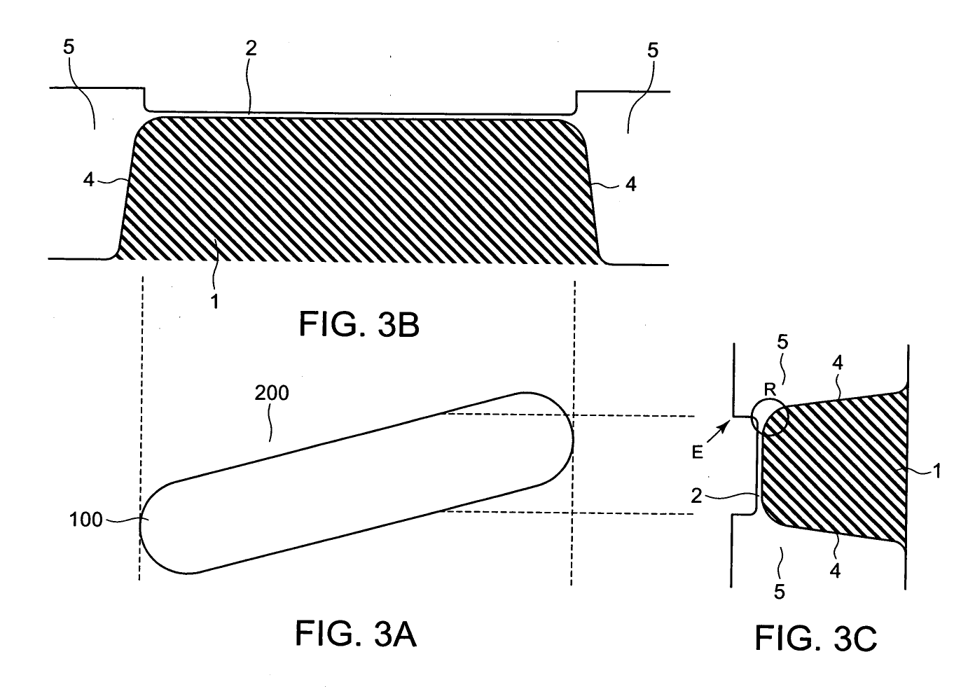

FIG. 1 is a plan view showing memory cells of a DRAM having a plurality of active regions. FIGS. 2A-2C to FIGS. 11A-11C show a series of manufacturing processes, wherein FIGS. 2A, 3A, . . . , 11A each show (A) a plan view of one of the active regions, FIGS. 2B, 3B, . . . , 11B each show (B) a sectional view in a long-side direction of the active region, and FIGS. 2C, 3C, . . . , 11C each show (C) a sectional view in a short-side direction of the active region.

As shown in the plan view of FIG. 1, a plurality of active regions 100 surrounded by an element isolation region 200 are regularly arranged in the memory cells of the DRAM. Word lines 16 are arranged at regular intervals so as to cross the active regions 100 in a longitudinal direction (vertical direction in FIG. 1). Trench-gate transistors are provided at intersecting portions, with the word lines 16, of the active regions 100, respectively. Although not illustrated, bit lines are provided so as to extend in a direction perpendicular to the word lines 16 (lateral direction in FIG. 1). The active regions 100 are each slightly inclined with respect to a horizontal line (lateral direction in FIG. 1), but this is based on a design and one of various inclination angles can be selected.

At first, as shown in FIGS. 2A-2C, the element isolation region 200 is formed. FIG. 2A shows the state in a plan view where the active region 100 is surrounded by the element isolation region 200. FIG. 2B shows a section in a long-side direction of the active region 100 and FIG. 2C shows a section in a short-side direction of the active region 100. A pad oxide film 2 (e.g. thickness: 10 nm) in the form of a silicon oxide film and a silicon nitride film 3 (e.g. thickness: 120 nm) are stacked on the surface of a silicon substrate 1. Thereafter, the silicon nitride film 3 and the pad oxide film 2 are processed by lithography and dry etching so as to form a pattern of the active regions 100, thereby exposing the surface of the silicon substrate 1 in a region which is to serve as the element isolation region 200. Then, the silicon substrate 1 is dry-etched using the silicon nitride film 3 as a mask, thereby forming a trench 4 (e.g. depth: 250 nm). Then, a buried oxide film 5 (e.g. thickness: 550 nm) is formed by CVD (Chemical Vapor Deposition). Then, the surface of the buried oxide film 5 is flattened by CMP (Chemical Mechanical Polishing), thereby forming the element isolation region 200. In this event, the remaining thickness of the silicon nitride film 3 becomes about 70 nm. At this stage, as shown in FIGS. 2B and 2C, a rounded portion R is formed at a side-wall shoulder portion of the active region 100 in order to improve the transistor characteristics. The radius of curvature of the rounded portion R becomes about 20 nm.

Then, as shown in FIGS. 3A-3C, the silicon nitride film 3 is removed using thermal phosphoric acid, thereby exposing the pad silicon film 2. As a result, an end portion E of the buried oxide film 5 remains over the rounded portion R. At this stage, a level difference between the surface of the pad oxide film 2 and the surface of the end portion E of the buried oxide film 5 is about 20 nm.

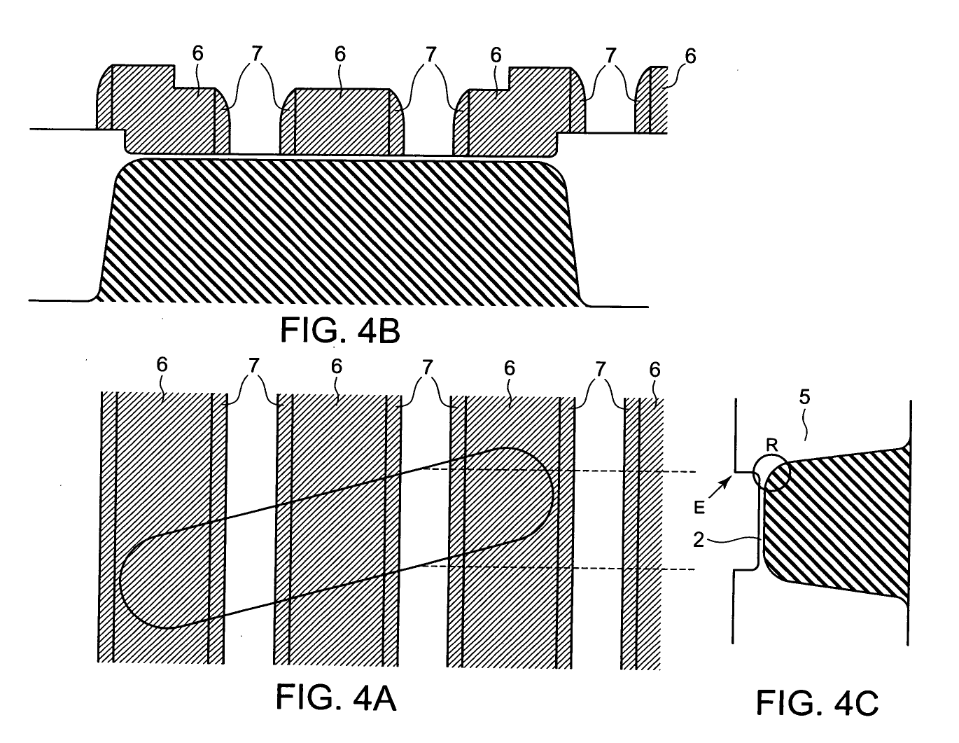

Then, as shown in FIGS. 4A-4C, a pattern of a silicon nitride film 6 (e.g. thickness: 80 nm) is formed as a trench-forming mask. Further, side walls 7 in the form of silicon nitride films are formed.

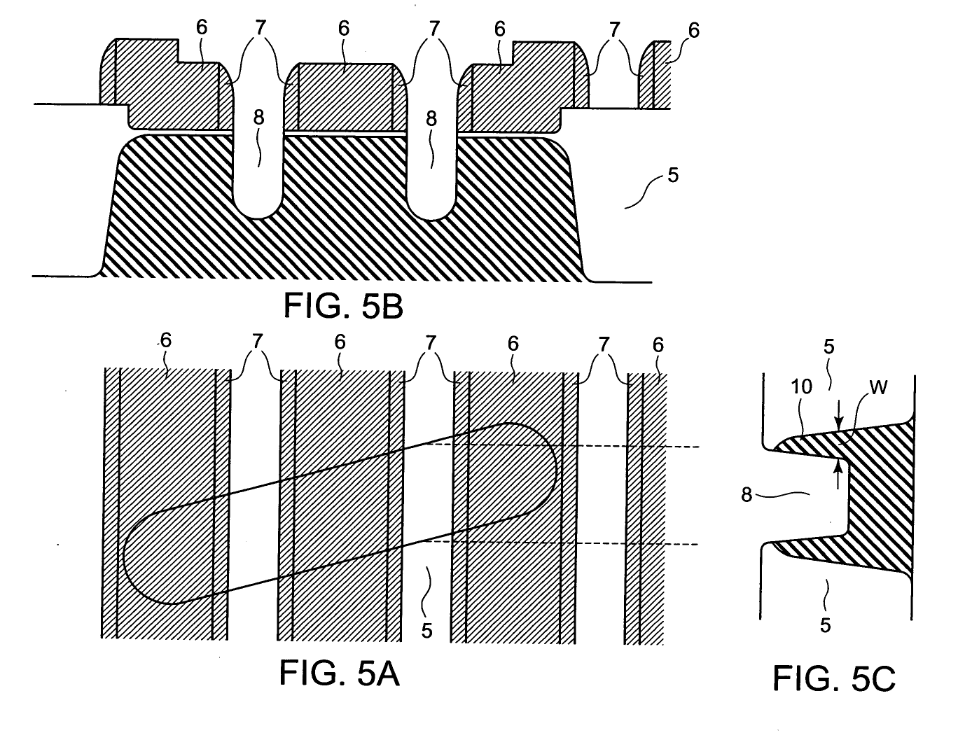

Then, as shown in FIGS. 5A-5C, the exposed pad oxide film 2 is dry-etched. Further, the silicon substrate 1 is dry-etched, thereby forming trenches 8 (e.g. depth: 150 nm). In this event, as shown in FIG. 5C, in the section in the short-side direction where the buried oxide film 5 and the trench 8 are adjacent to each other, a silicon etching residue 10 remains on the side wall of the buried oxide film 5. The thickness W of the silicon etching residue 10 at the trench bottom becomes about 30 nm.

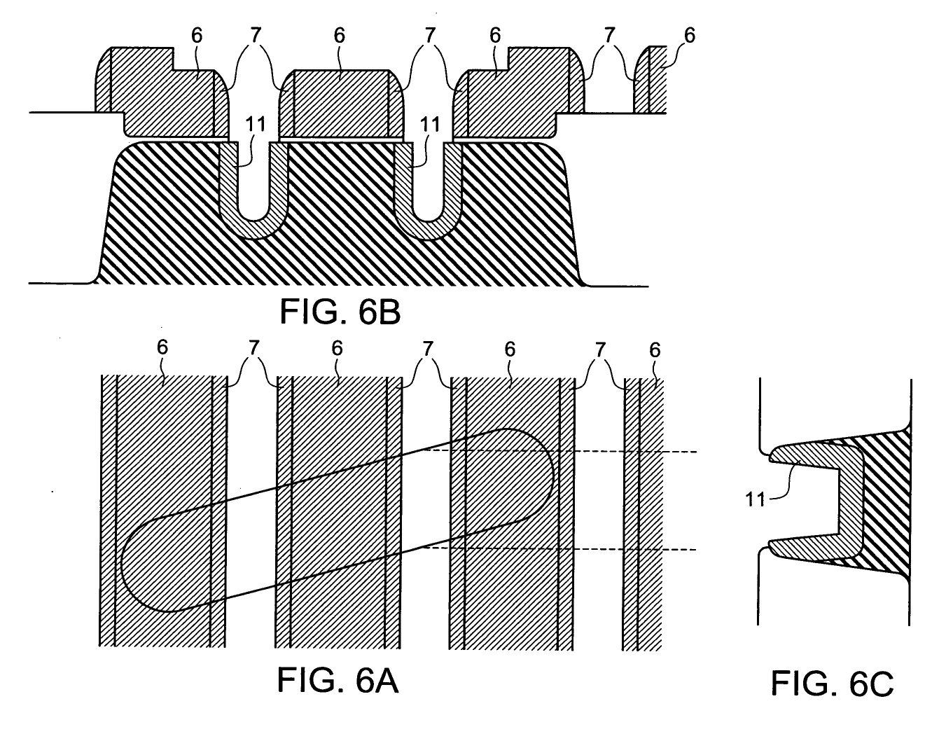

Since the silicon etching residue 10 impedes the transistor operation, it should be removed. Therefore, as shown in FIGS. 6A-6C, the exposed surface of the silicon substrate 1 is oxidized by thermal oxidation, thereby forming a sacrificial oxide film 11 (e.g. thickness: 50 nm) in each trench 8. The sacrificial oxide film 11 is formed at the inner wall of each trench 8 not only in the section shown in FIG. 6C, but also in the section shown in FIG. 6B. As is well known, the silicon substrate 1 is consumed by a thickness of 25 nm for forming a thermal oxide film having a thickness of 50 nm.

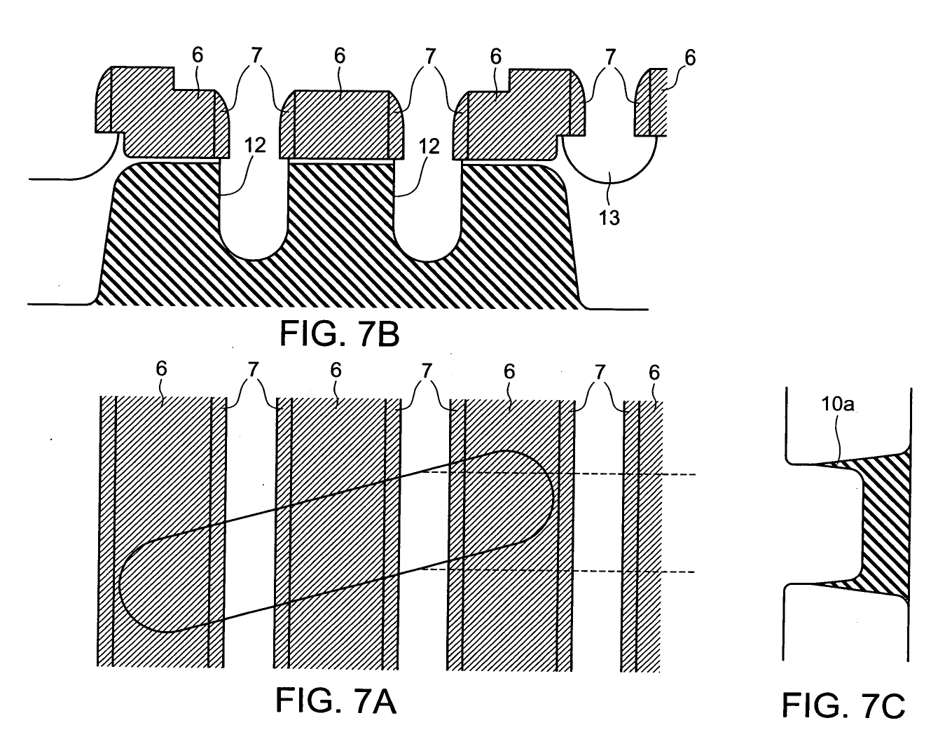

Then, as shown in FIGS. 7A-7C, the sacrificial oxide films 11 are wet-etched with a solution containing hydrofluoric acid. As a result, the silicon etching residue 10 has a reduced thickness of 10 nm or less so as to be a silicon etching residue 10a as shown in FIG. 7C. On the other hand, as shown in FIG. 7B, there are formed new trenches 12 each having a width increased, for example, by 50 nm. Further, since there is no alternative but to use the solution etching for removing the sacrificial oxide films 11, the surface of the buried oxide film 5 exposed in the element isolation region is also etched and thus recesses 13 are formed.

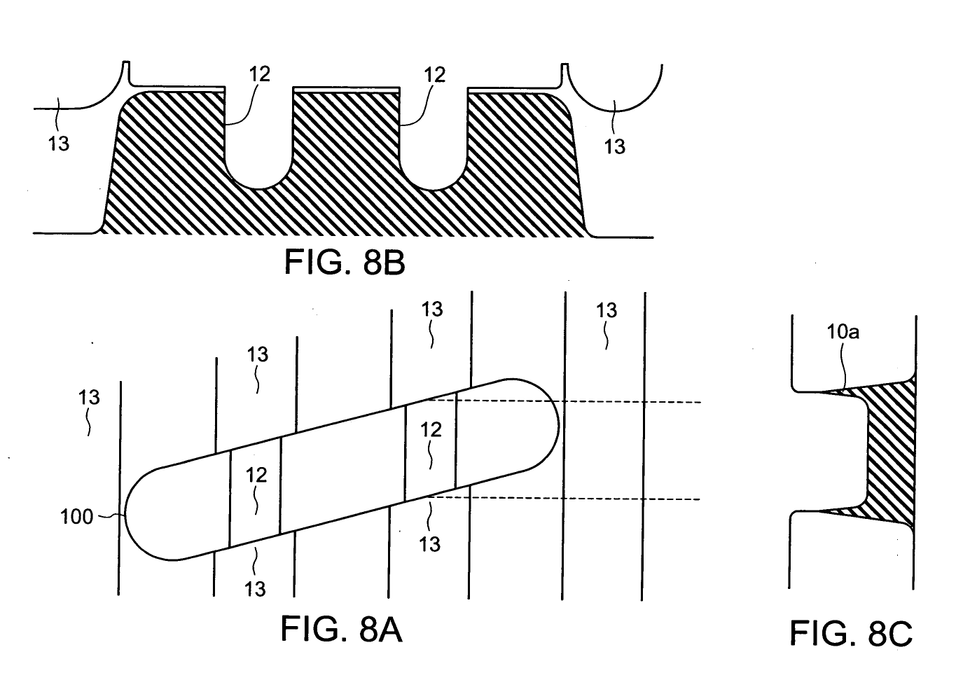

Then, as shown in FIGS. 8A-8C, the silicon nitride film 6 and the side walls 7 used as the mask are selectively removed by thermal phosphoric acid.

In the foregoing manner, as shown in FIG. 8A, the trenches 12 having the increased width are formed in the active region 100 and the recesses 13 are formed in the element isolation region.

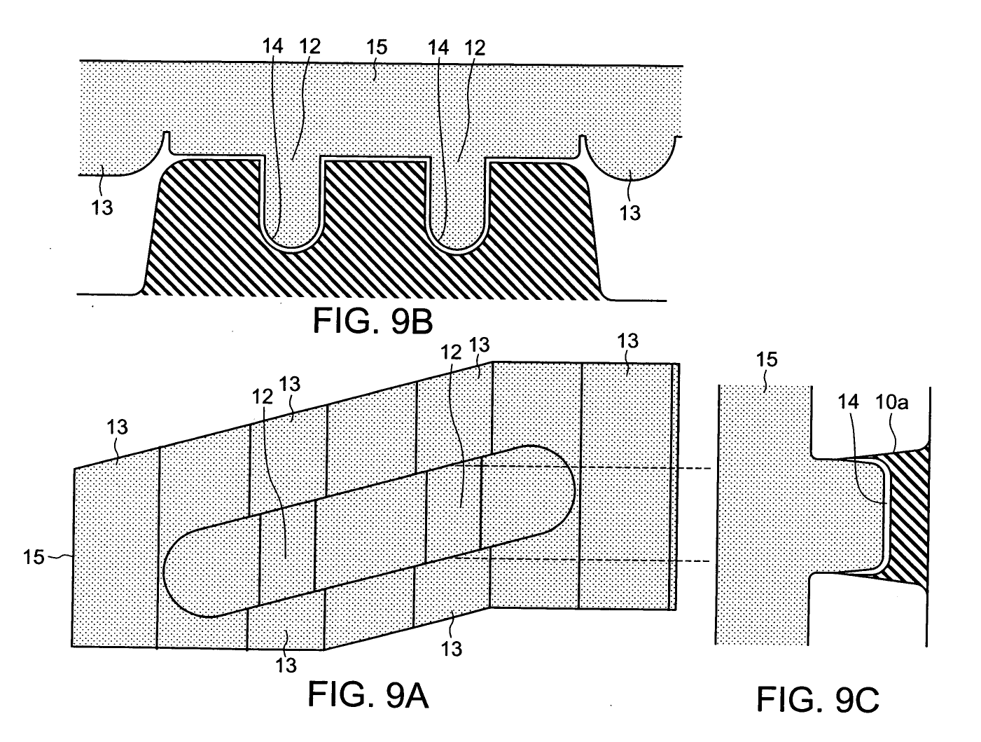

Then, as shown in FIGS. 9A-9C, a gate oxide film 14 (e.g. thickness: 6 nm) is formed at the inner surface of each trench 12. Further, a stacked film 15 to be gate electrodes is formed over the entire surface. The stacked film 15 is formed by a conductor such as a polycrystalline silicon film and an insulator such as a silicon nitride film formed thereon.

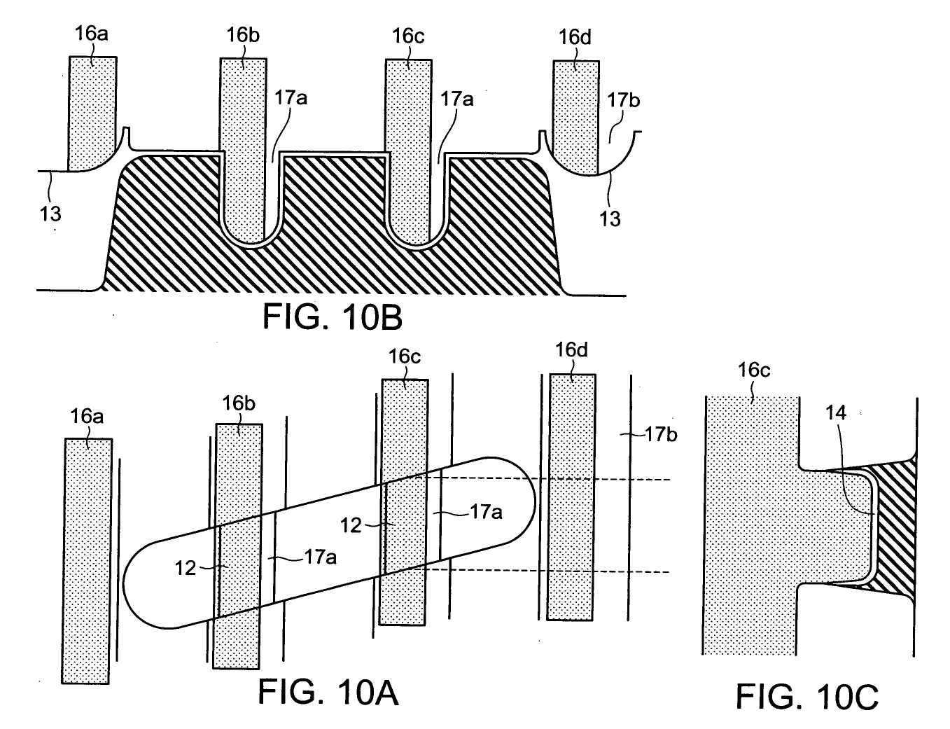

Then, as shown in FIGS. 10A-10C, the stacked film 15 is processed by lithography and dry etching, thereby forming word lines 16a, 16b, 16c, and 16d which are to serve as the gate electrodes. In this event, since the width of each trench 12 is increased to be larger than a predetermined width (i.e. the width of each trench 8 in FIG. 5B), a gap 17a is formed in each of the trenches 12 where the word lines 16b and 16c are formed, respectively. Further, a gap 17b is formed in each of the recesses 13 in the element isolation region where the word lines 16a and 16d are formed, respectively.

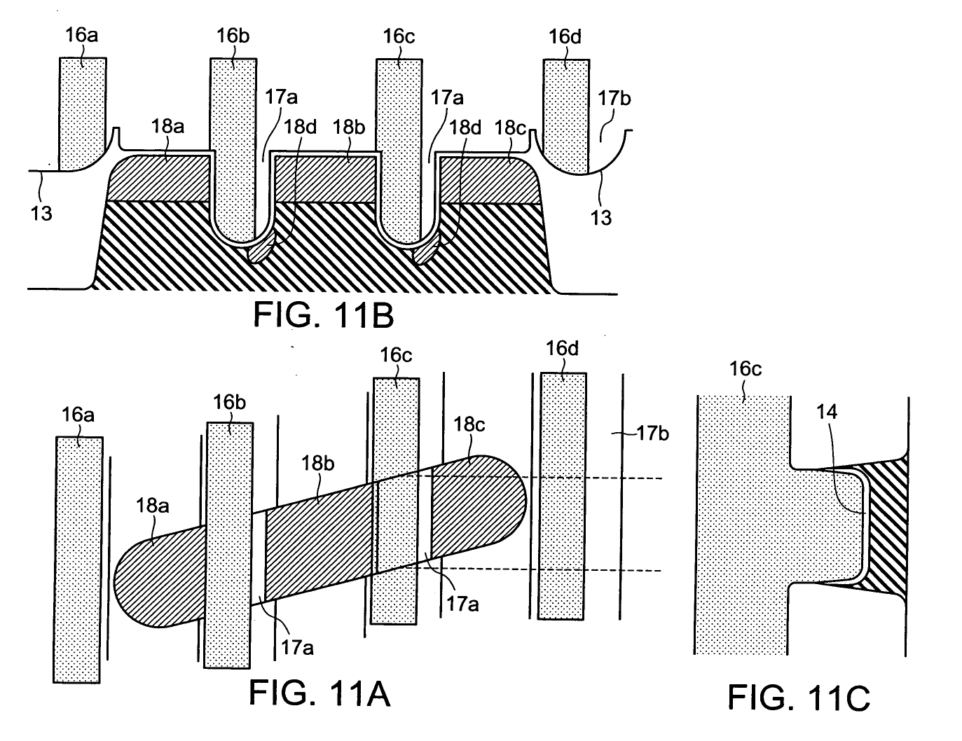

Then, as shown in FIGS. 11A-11C, impurities are introduced into the silicon substrate surface by ion implantation using the word lines as a mask, thereby forming source diffusion layers 18a and 18c and a drain diffusion layer 18b. In this event, since the gaps 17a are formed in the trenches 12, the ions are also implanted into regions which should not be subjected to the ion implantation, resulting in that unwanted diffusion layers 18d are formed.

As described above, in the related trench gate forming method, there is a problem that the width of the trenches formed in the active regions increases to thus make it impossible to form the transistors precisely following the design size. Further, there is also a problem that the large recesses are formed in the element isolation region due to the wet etching and thus the flatness of the surface is irregularly impaired, resulting in a reduction in manufacturing yield.

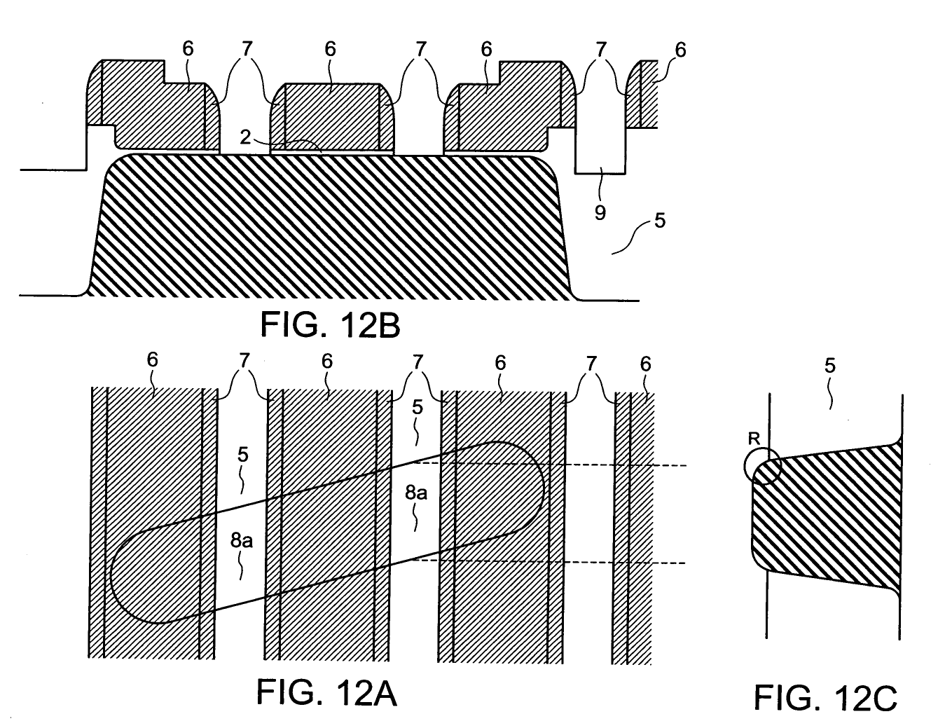

Now, the best modes for carrying out this invention will be described in detail. A description will be omitted of those portions overlapping the related trench gate forming method. The same members as those of the related semiconductor device will be described using the same reference symbols. In the following description, FIGS. 12A, 14A-16A, 18A, and 19A have the same viewpoint as FIGS. 2A, 3A, . . . , 11A, FIGS. 12B, 14B-16B, 18B, and 19B have the same viewpoint as FIGS. 2B, 3B, . . . , 11B, and FIGS. 12C, 14C-16C, 18C, and 19C have the same viewpoint as FIGS. 2C, 3C, . . . , 11C.

### First Embodiment

The first embodiment of this invention will be described with reference to FIGS. 12A to 17. FIGS. 12A-12C are the first figures for describing a process subsequent to FIGS. 4A-4C used in the description of the related art.

At first, as shown in FIGS. 12A-12C, according to the same processes as those of the related art, the element isolation region is formed using the buried oxide film 5 and then the pattern of the silicon nitride film 6 and side walls 7 is formed as the trench-forming mask. In the related art, the trenches are subsequently formed. However, in this embodiment, the buried oxide film 5 in those regions adjacent to trench-forming regions 8a is removed before forming trenches. Specifically, the end portions of the buried oxide film 5 covering the rounded portions R of the active regions are removed.

Herein, it is assumed that the surface of the buried oxide film 5 before the removal is located at a position higher than the silicon substrate surface by 30 nm and that the radius of curvature of the rounded portion R is 20 nm. In this case, the buried oxide film 5 is etched by 50 nm from its surface so that the surface of the buried oxide film 5 is located at a position lower than the silicon substrate surface by 20 nm. By this etching, the trenches can be formed in the state where the upper-surface position of the active region is located higher than the upper-surface position of the buried oxide film.

A parallel-plate (or capacitive coupled) plasma etching apparatus can be used for the etching of the buried oxide film 5. For example, the buried oxide film 5 can be etched by 50 nm under the conditions of C₄F₈/Ar/O₂ at 10/500/5 (sccm), a pressure of 50 mTorr, RF of 800 W, and an etching time of 30 seconds. By this etching, the side-wall shoulder portions R of the trench-forming regions 8a can be exposed. The silicon etching amount under such conditions is 2.5 nm and thus it is possible to substantially prevent etching of the side-wall shoulder portions R of the trench-forming regions 8a. Instead of C₄F₈ (octafluorocyclobutane), use can be made of one or two or more of high-order fluorocarbon gases such as C₅F₈ (octafluorocyclopentene) and C₄F₆ (hexafluorocyclobutane) as an etching gas. However, the foregoing etching cannot be realized with a low-order fluorocarbon gas such as CF₄.

In the foregoing etching of the buried oxide film 5, since there is no material having a different etching rate present in a depth region where the etching should be stopped, etching end point detection is extremely important. In this embodiment, the etching end point detection is carried out by a plasma luminescence intensity analysis (or an emission spectle analysis). Specifically, attention is paid to the luminescence intensity at a wavelength of 440 nm caused by excitation of SiF molecules (depending on SiF molecular weight) and the luminescence intensity at a wavelength of 260 nm caused by excitation of CF molecules (depending on CF molecular weight) present in a plasma during the etching, thereby detecting the etching end point using those luminescence intensities. More specifically, a monitor signal waveform indicating changes in the ratio between SiF luminescence intensity and CF luminescence intensity is differentiated to thereby derive an inflection point as the etching end point. The etching end point may be automatically detected by a monitoring device and used for controlling a stop of the etching.

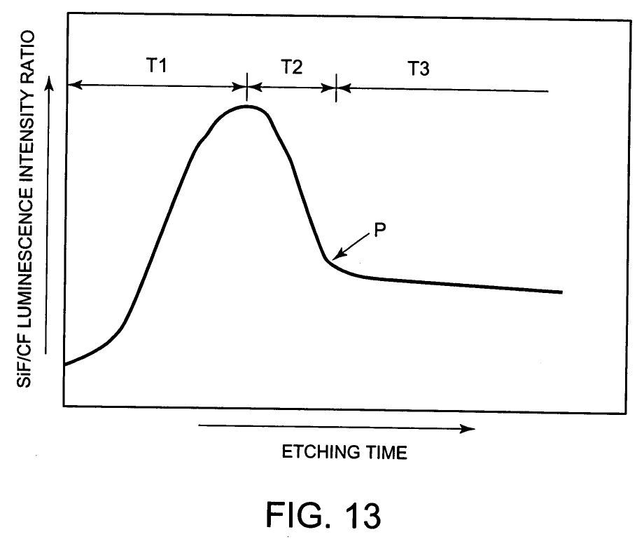

FIG. 13 shows time-dependent changes of the SiF/CF luminescence intensity ratio (differentiated waveform) when the etching is performed under the foregoing etching conditions in the state where the trench-forming region 8a is coated with the pad oxide film 2 and the end portion of the buried oxide film 5 covers the rounded portion R. Based on this monitor waveform, the plasma etching state can be divided into three regions of T1, T2, and T3. Since the entire surface is coated with the silicon oxide film at the start of the etching, the SiF luminescence intensity increases with the progress of the etching. Since the CF luminescence does not change, the SiF/CF luminescence intensity ratio increases comparatively (region of T1). When the pad oxide film 2 in the form of the silicon oxide film has been etched so that the silicon of the trench-forming region 8a starts to be exposed, the carbon contained in C₄F₈ starts to adhere to the surface of the exposed silicon so that the silicon is prevented from being etched. Thus, the etching area is resultantly reduced so that the SiF luminescence intensity decreases (region of T2). When the etching further proceeds so that the rounded portion R is exposed, there is no change in etching area. As a result, the etching is confined to a constant area occupied only by the buried oxide film 5 and therefore the SiF/CF luminescence intensity ratio becomes constant (region of T3). In this sequence of changes in the SiF/CF luminescence intensity ratio, a distinct inflection point P can be detected at the boundary from the region of T2 to the region of T3 where the rounded portion R is exposed. By the detection of the inflection point P, it is possible to judge that the rounded portion R has been exposed. Basically, the etching is finished when the inflection point P is detected. However, overetching may be carried out from the inflection point P in consideration of the margin for various variations. The overetching time is set to about 20% of a time corresponding to the region of T2. For improving the detection accuracy of the inflection point P in this luminescence monitoring, it is possible to adjust the thickness of the pad oxide film 2 and the thickness of the silicon nitride film 3 formed thereon. It is also possible to adjust the remaining thicknesses of the silicon nitride film 3 and the buried oxide film 5 by the CMP which is carried out after the formation of the buried oxide film 5 for flattening the surface.

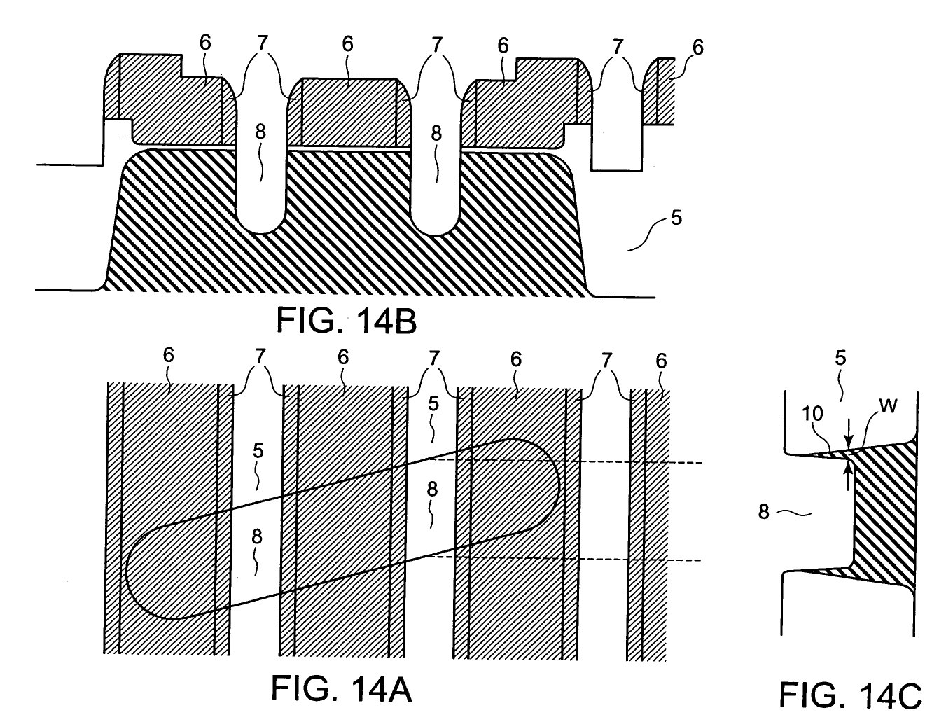

Then, as shown in FIGS. 14A-14C, trenches 8 are formed by dry etching. For this dry etching, a commercial ICP (Inductive Coupled Plasma) dry etching apparatus can be used. The trench having a depth of 150 nm can be formed under the conditions of HBr/Cl₂/O₂: 100/100/10 (sccm) used as an etching gas, a pressure of 4 mTorr, a high-frequency power of 500 W, a bias high-frequency power of 150 W, and an etching time of 25 seconds. In this event, the etching amount of the buried oxide film 5 is about 1 nm and thus it is hardly etched. As a result, a silicon etching residue 10 remaining on the side wall of the buried oxide film 5 has a width W of 8 nm at the trench bottom. Accordingly, it can be largely improved as compared with the related art in which the silicon etching residue has a width W of 30 nm at the trench bottom. Therefore, the formation of the thick sacrificial oxide film for removing the silicon etching residue, which is performed in the related art, is not required.

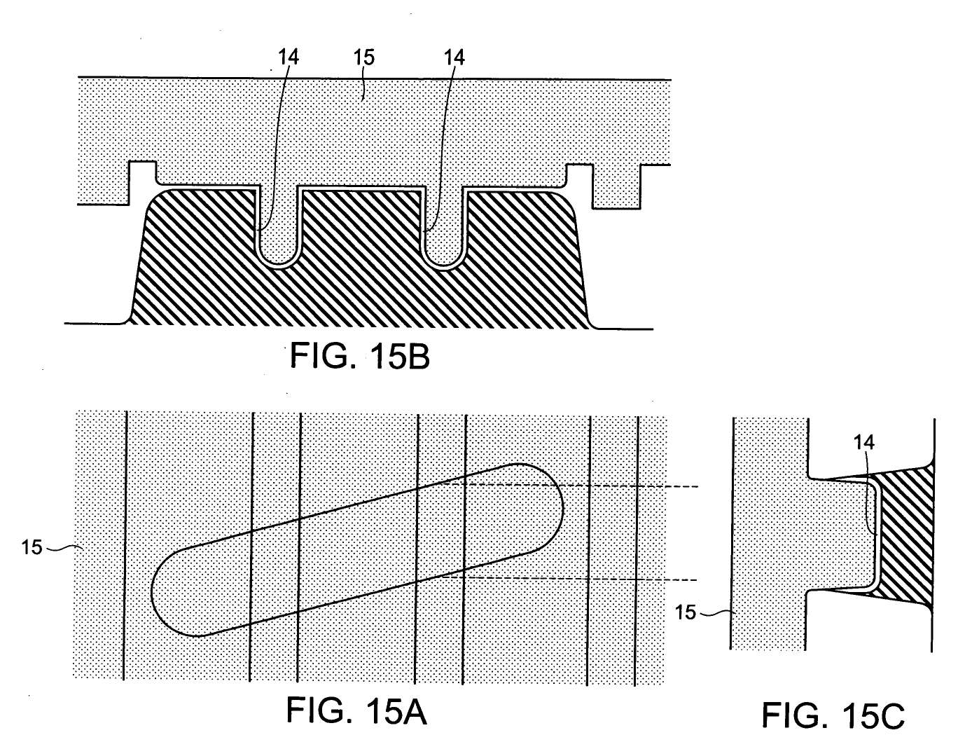

Then, as shown in FIGS. 15A-15C, after selectively removing the silicon nitride film 6 and the side walls 7 using thermal phosphoric acid, a gate oxide film 14 (e.g. thickness: 6 nm) is formed at the inner surface of each trench 8 and then a stacked film 15 to be gate electrodes is formed over the entire surface. Before forming the gate oxide film 14, a sacrificial oxide film (e.g. thickness: 10 nm) is formed and removed for the purpose of removing dry-etching damage of the inner surface of each trench. This causes, as shown in FIG. 15C, the silicon etching residue 10 to substantially disappear after the formation of the gate oxide film 14. The stacked film 15 is formed by forming a polycrystalline silicon film by CVD, then flattening the surface by CMP, and then stacking a tungsten silicide film, a tungsten nitride film, a tungsten film, and a silicon nitride film. The metal and metal compound films included in the stacked film 15 may be formed using a material other than tungsten.

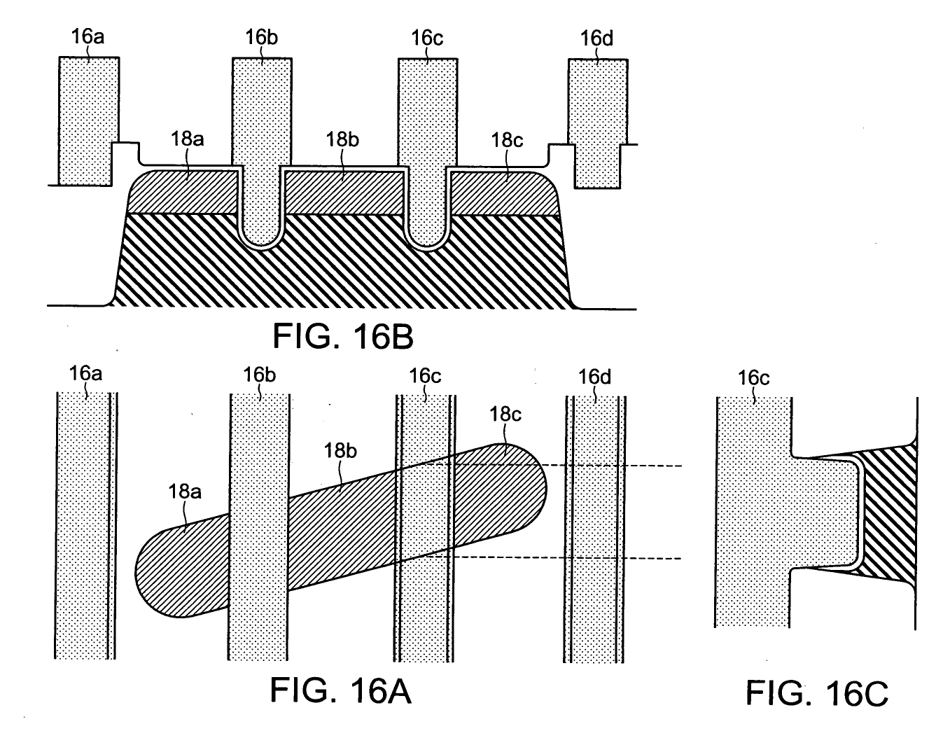

Then, as shown in FIGS. 16A-16C, the stacked film 15 is processed by lithography and dry etching, thereby forming word lines 16a, 16b, 16c, and 16d which are to serve as the gate electrodes. Further, phosphorus is ion-implanted using the word lines as a mask, thereby forming source diffusion layers 18a and 18c and a drain diffusion layer 18b. As different from the related art, since the width of the trenches 8 is not increased in this embodiment, no gap is formed in the trenches after the formation of the word lines and thus there is no problem of formation of unwanted diffusion layers in improper regions.

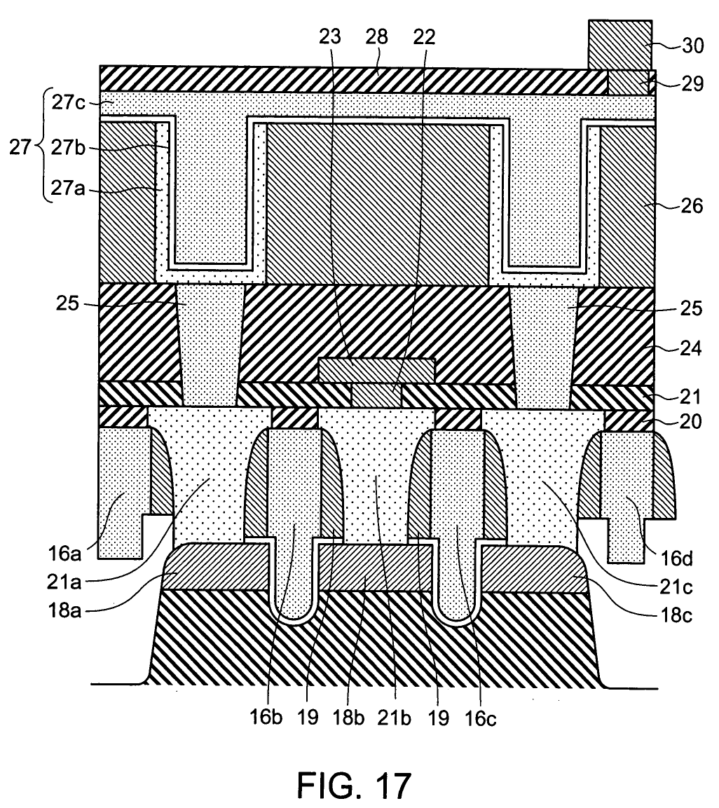

Then, as shown in FIG. 17, side walls 19 in the form of silicon nitride films are formed on the side walls of the word lines 16a, 16b, 16c, and 16d and, after forming an interlayer insulating film 20 over the entire surface, cell contact plugs 21a, 21b, and 21c are formed so as to be connected to the diffusion layers 18a, 18b, and 18c, respectively. Thereafter, an interlayer insulating film 21 is formed over the entire surface and then a bit-line contact plug 22 and a bit line 23 are formed on the cell contact plug 21b. Thereafter, an interlayer insulating film 24 is formed over the entire surface and then capacitance contact plugs 25 are formed on the cell contact plugs 21a and 21c, respectively. Thereafter, an interlayer insulating film 26 is formed over the entire surface and then a capacitor 27 comprising lower electrodes 27a, a capacitance insulating film 27b, and an upper electrode 27c is formed so as to be connected to the capacitance contact plugs 25. Thereafter, an interlayer insulating film 28 is formed over the entire surface and then a contact plug 29 and an upper wiring layer 30 are formed, thereby completing a DRAM.

As described above, according to this embodiment, the end portions of the buried oxide film 5 covering the rounded portions R are removed before the formation of the trenches 8, so that the trenches 8 are formed in the state where the upper surface of each active region is located higher than the upper surface of the buried oxide film 5. Therefore, it is possible to suppress the occurrence of the silicon etching residues on the side walls of the buried oxide film 5 after the formation of the trenches 8, thereby making it possible to manufacture the semiconductor device having the trench-gate transistors precisely following the design size.

### Second Embodiment

In the foregoing first embodiment, the removal of the end portions of the buried oxide film 5 covering the rounded portions R is performed after the process of FIGS. 4A-4C shown in the related art. That is, after forming the pattern of the silicon nitride film 6 and side walls 7 to serve as the trench-forming mask, the removal of the end portions of the buried oxide film 5 covering the rounded portions R is performed. Therefore, as shown in FIGS. 12A-12C, recesses 9 each having a depth of about 50 nm are formed in the element isolation region after the removal.

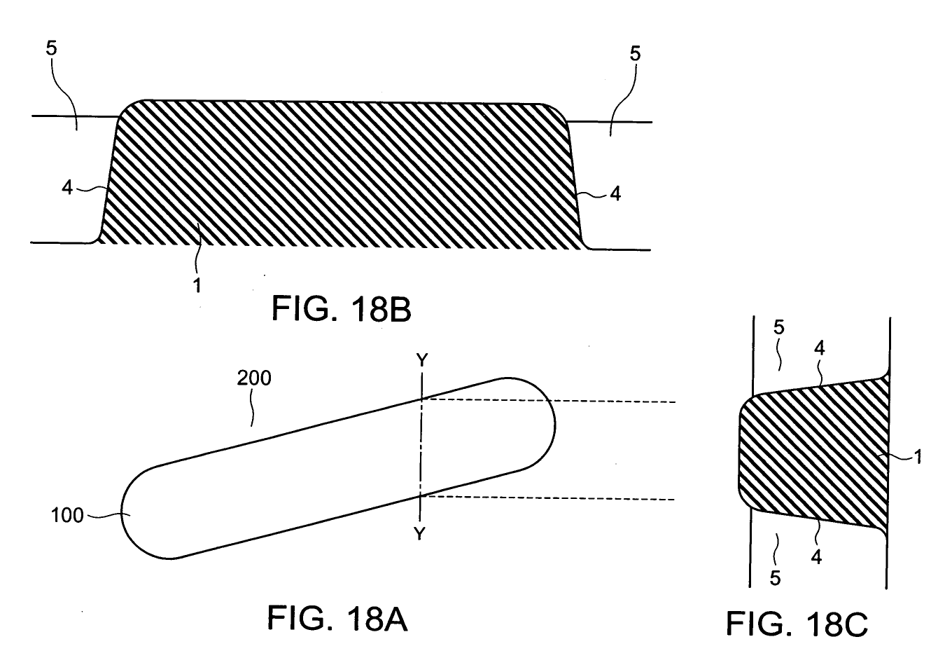

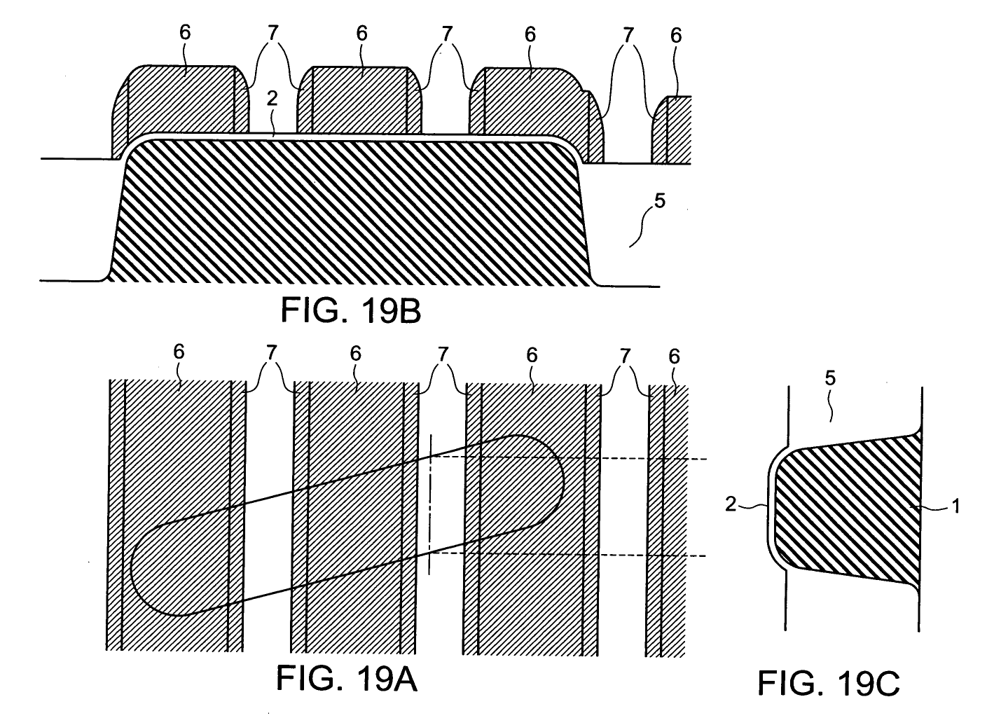

In this embodiment, the removal of the end portions of the buried oxide film 5 covering the rounded portions R is performed after the process of FIGS. 2A-2C or FIGS. 3A-3C of the related art. Thus, as shown in FIGS. 18A-18C, the whole of the element isolation region 200 surrounding the active region 100 is etched to a position lower than the upper surface of the active region 100. Thereafter, as shown in FIGS. 19A-19C, a pad oxide film 2 is formed and then a pattern of a silicon nitride film 6 and side walls 7 is formed as a trench-forming mask, which can prevent the formation of the recesses 9.

In the foregoing second embodiment, since the dry etching is used for the formation of the gate trenches, the etching of the silicon oxide film can be suppressed to about 1/100. Accordingly, the element isolation region is formed with recesses each having a depth only corresponding to the thickness of the pad oxide film 2 (about 10 nm). Therefore, as compared with the related art in which the large recesses 13 (FIGS. 7A-7C) are formed in the element isolation region due to the wet etching so that the parasitic capacitance of the word lines increases, it is possible, in this embodiment, to suppress an increase in opposing area between the word lines and the diffusion layers and thus to suppress an increase in parasitic capacitance of the word lines.

Further, in the foregoing first and second embodiments, since it is possible to reduce the thickness of the silicon etching residues that are formed on the side walls of the element isolation region adjacent to the gate trenches in the formation of the gate trenches, it is possible to reduce the formation amount of the sacrificial oxide film formed in each gate trench thereafter and its etching amount. As a result, it is possible to prevent an increase in width of the gate trenches and thus to manufacture the semiconductor device having the trench-gate transistors precisely following the design size. Further, there is no formation of unwanted diffusion layers. Moreover, it is possible to prevent the buried oxide film of the element isolation region from being etched more than required and thus to improve the manufacturing yield.

What is claimed is:

1. A method of manufacturing a semiconductor device having a trench-gate transistor in an active region surrounded by an element isolation region, said method comprising the steps of:
forming a buried oxide film in said element isolation region and flattening said buried oxide film;
selectively etching said buried oxide film in a region adjacent to a trench-forming region, so that a position of an upper surface of said buried oxide film in said region adjacent to said trench-forming region is located lower than a position of an upper surface of said active region; and
forming, thereafter, a gate trench in said trench-forming region.

2. The method according to claim 1, wherein said active region comprises a side-wall shoulder portion having a rounded shape, and
said step of selectively etching said buried oxide film etches an end portion of said buried oxide film, said end portion covering said side-wall shoulder portion having the rounded shape.

3. The method according to claim 1, wherein said active region is formed by a silicon substrate, and
said step of selectively etching said buried oxide film is performed by dry etching using a gas containing a fluorocarbon gas.

4. The method according to claim 3, wherein said fluorocarbon gas contains one or two or more of C₄F₈, C₅F₈, and C₄F₆.

5. The method according to claim 3, wherein said dry etching is stopped based on detection of an end point by an emission spectral analysis.

6. The method according to claim 5, wherein said detection of the end point by the emission spectral analysis is performed by monitoring a ratio between SiF molecular luminescence intensity and CF molecular luminescence intensity.

7. The method according to claim 5, wherein, for facilitating said detection of the end point, selective etching of said buried oxide film is started in a state where a silicon oxide film or a silicon nitride film formed at the upper surface of said active region remains.

8. A semiconductor device having a trench-gate transistor in an active region surrounded by an element isolation region, said semiconductor device manufactured by the steps of:
forming a buried oxide film in said element isolation region and flattening said buried oxide film;
selectively etching said buried oxide film in a region adjacent to a trench-forming region, so that a position of an upper surface of said buried oxide film in said region adjacent to said trench-forming region is located lower than a position of an upper surface of said active region; and
forming, thereafter, a gate trench in said trench-forming region.

9. The semiconductor device according to claim 8, wherein said active region comprises a side-wall shoulder portion having a rounded shape, and
said step of selectively etching said buried oxide film etches an end portion of said buried oxide film, said end portion covering said side-wall shoulder portion having the rounded shape.

10. The semiconductor device according to claim 8, wherein said active region is formed by a silicon substrate, and
said step of selectively etching said buried oxide film is performed by dry etching using a gas containing a fluorocarbon gas.

11. The semiconductor device according to claim 10, wherein said fluorocarbon gas contains one or two or more of C₄F₈, C₅F₈, and C₄F₆.

12. The semiconductor device according to claim 10, wherein said dry etching is stopped based on detection of an end point by an emission spectral analysis.

13. The semiconductor device according to claim 12, wherein said detection of the end point by the emission spectral analysis is performed by monitoring a ratio between SiF molecular luminescence intensity and CF molecular luminescence intensity.

14. The semiconductor device according to claim 13, wherein, for facilitating said detection of the end point, selective etching of said buried oxide film is started in a state where a silicon oxide film or a silicon nitride film formed at the upper surface of said active region remains.
